(19) United States
(12) Patent Application Publication
(10) Pub. No.: US 2024/0079397 A1
(43) Pub. Date: Mar. 7, 2024

(54) LED Display Module and LED Display Device

(71) Applicant: SHENZHEN LEYARD OPTO-ELECTRONIC CO., LTD., Shenzhen (CN)

(72) Inventors: Qingfeng LI, Shenzhen (CN); Ming LIU, Shenzhen (CN); Xuechao SUN, Shenzhen (CN)

(21) Appl. No.: 18/236,411

(22) Filed: Aug. 22, 2023

(30) Foreign Application Priority Data
Sep. 7, 2022 (CN) 202211091234.2

(51) Int. Cl. H01L 25/16; H05K 5/02

(52) U.S. Cl. CPC H01L 25/167; H05K 5/0204; H05K 5/0208; H05K 5/0221

(57) ABSTRACT

The present disclosure provides an LED display module and an LED display device. The LED display module includes a display module body and a lock. The lock includes: a lock seat arranged on a rear side of the display module body; a lock cylinder rotatably arranged in the lock seat; a locking member; an interference member rotatably sleeved on the lock cylinder and spaced apart from the locking member along the axial direction of the lock cylinder, the interference member having an interference position where the interference member locates on a front side of a connecting beam for lifting up the display module body and an avoidance position where the interference member avoids the connecting beam; and an elastic linkage member arranged between the locking member and the interference member. When the locking member is in an unlocking position, the interference member is driven to an interference position by the elastic linkage member. When the locking member rotates from the unlocking position to a locking position, the interference member rotates from the interference position to the avoidance position.

### CROSS REFERENCE TO RELATED APPLICATIONS

The present disclosure claims benefit of Chinese Patent Application No. 202211091234.2, filed on Sep. 7, 2022, entitled “LED Display Module and LED Display Device”, the contents of which are hereby incorporated by reference in its entirety.

### TECHNICAL FIELD

The present disclosure relates to the technical field of Light Emitting Diode (LED) display, and more particularly, to an LED display module and an LED display device.

### BACKGROUND

An LED display device is a flat panel display for displaying various pieces of information such as text, images, video, and video signals. The LED display device includes an LED display module and a box.

The LED display device in the related technology mounts the LED display module on the box by multiple locks. However, since there are a large number of locks, the problem of missing locking is easily caused.

### SUMMARY

A main object of the present disclosure is to provide an LED display module and an LED display device, so as to solve the problem in the related technology that missing locking is easily caused when an LED display module is mounted on a box by locks.

In order to achieve the above-mentioned object, according to one aspect of the present disclosure, there is provided an LED display module including a display module body and a lock. The lock includes: a lock seat arranged on a rear side of the display module body; a lock cylinder rotatably arranged in the lock seat; a locking member connected with the lock cylinder and rotating synchronously with the lock cylinder, the locking member having a locking position abutting against a rear side of the connecting beam to lock the display module body on the connecting beam, and an unlocking position avoiding the connecting beam so that the display module body is separable from the box; an interference member rotatably sleeved on the lock cylinder, the interference member being spaced apart from the locking member along the axial direction of the lock cylinder, the interference member having an interference position where the interference member locates on a front side of the connecting beam to lift forward the display module body and an avoidance position where the interference member avoids the connecting beam; and an elastic linkage member arranged between the locking member and the interference member. When the locking member is in the unlocking position, the interference member is driven to the interference position by the elastic linkage member, and when the locking member rotates from the unlocking position to the locking position, the interference member rotates from the interference position to the avoidance position.

In some embodiments, the interference member includes a rotating sleeve sleeved outside of the lock cylinder and an interference arm connected with an outer side wall of the rotating sleeve, a first end of the elastic linkage member is connected with the locking member, and a second end of the elastic linkage member is connected with the interference arm.

In some embodiments, the elastic linkage member includes a torsion spring, an end portion of a first torsion arm of the torsion spring is inserted into the locking member, and an end portion of a second torsion arm of the torsion spring is inserted into the interference arm.

In some embodiments, the interference member further includes a first drive block connected with the outer side wall of the rotating sleeve, the first drive block is spaced apart from the interference arm, the locking member includes a locking arm and a second drive block arranged on the side of the locking arm facing the rotating sleeve, the dimension of the interference arm extending along the radial direction of the rotating sleeve is greater than the dimension of the first drive block extending along the radial direction of the rotating sleeve, and the second drive block is in drive fit with the first drive block so that the interference member is driven to rotate from the interference position to the avoidance position when the locking member rotates from the unlocking position to the locking position.

In some embodiments, the lock cylinder includes a lock plate rotatably arranged at the lock seat and a cylinder rod penetrating through the lock plate, a front portion of the cylinder rod is provided with a front operating hole, and a rear portion of the cylinder rod is in rotation stopping fit with the locking member.

In some embodiments, the lock seat is provided with a first limiting portion, the lock plate is provided with a second limiting portion in limiting fit with the first limiting portion, and the first limiting portion is in limiting fit with the second limiting portion so as to limit the rotation range of the lock plate, so that the locking member is switched between the unlocking position and the locking position.

In some embodiments, the first limiting portion includes a limiting column, the second limiting portion includes a limiting hole, the limiting column penetrates through the limiting hole. the limiting hole extends along the circumferential direction of the lock plate, the limiting column has a first limiting position and a second limiting position in limiting fit with hole side walls at two ends of the limiting hole respectively, when the limiting column is in the first limiting position, the locking member is in the unlocking position, and when the limiting column is in the second limiting position, the locking member is in the locking position.

In some embodiments, the lock further includes a positioning ball and a first positioning hole and a second positioning hole in positioning fit with the positioning ball, the positioning ball is arranged on the lock seat, the first positioning hole and the second positioning hole are spaced apart on the lock plate, when the positioning ball is in positioning fit with the first positioning hole, the locking member is maintained in the unlocking position, and when the positioning ball is in positioning fit with the second positioning hole, the locking member is maintained in the locking position.

In some embodiments, the display module body is mounted on the connecting beam through a plurality of magnetic attraction structures, each of the plurality of the magnetic attraction structures includes a first magnetic attraction member and a second magnetic attraction member in magnetic attraction fit, the first magnetic attraction member is arranged on the display module body, and the second magnetic attraction member is arranged on the connecting beam. There are plurality of locks, at least one of the plurality of the locks is adjacent to one of the plurality of magnetic attraction structures, and when the interference member of the lock is in the interference position, the interference member is located between the first magnetic attraction member and the second magnetic attraction member of the magnetic attraction structure adjacent the interference member.

According to another aspect of the present disclosure, there is provided an LED display device including a box and an LED display module. A display module body is mounted on a connecting beam of the box, and the LED display module is the above-mentioned LED display module.

With the technical solution of the present disclosure, the LED display module is mounted on the connecting beam of the box, and the LED display module includes a display module body and a lock. The lock includes: a lock seat, a lock cylinder, a locking member, an interference member, and an elastic linkage member. The lock seat is arranged on a rear side of the display module body. The lock cylinder is rotatably arranged in the lock seat. The locking member is connected with the lock cylinder and rotates synchronously with the lock cylinder. The locking member has a locking position abutting against a rear side of the connecting beam to lock the display module body on the connecting beam, and an unlocking position avoiding the connecting beam so that the display module body is separable from the box. When operating from a front side of the LED display module, the rotation of the lock cylinder is driven by using a tool to lock the display module body on the connecting beam or to separate the display module body from the box. When operating from a rear side of the LED display module, the rotation of the locking member is directly driven to lock the display module body on the connecting beam or to separate the display module body from the box. The interference member is rotatably sleeved on the lock cylinder. And the interference member is spaced apart from the locking member along the axial direction of the lock cylinder, the interference member has an interference position located on a front side of the connecting beam to lift forward the display module body and an avoidance position staggered from the connecting beam. The elastic linkage member is arranged between the locking member and the interference member to enable the locking member to drive the interference member to switch between the interference position and the avoidance position by means of elasticity or linkage. When the locking member is in the unlocking position, the interference member is driven to the interference position by the elastic linkage member, and when the locking member rotates from the unlocking position to the locking position, the interference member rotates from the interference position to the avoidance position. In the process of mounting the LED display module of the LED display device on the box, when the locking member is in the unlocking position, under the action of the elastic linkage member acting as an elastic force, the interference member is located on the front side of the connecting beam so as to lift forward the display module body, so that a front surface of the LED display device is uneven, thereby reminding an operator to drive the lock cylinder so as to lock the display module body on the connecting beam, and avoiding the occurrence of missing locking. At this moment, the rotation of the lock cylinder is driven by using a tool or the rotation of the locking member is directly driven, so that the locking member is in the locking position, under the action of the elastic linkage member acting as a linkage, the interference member rotates together with the locking member, and the interference member can be in the avoidance position. At this moment, there is no interference between the LED display module and the box, and since the interference member is in the avoidance position staggered from the connecting beam, the LED display device can be fixed to the box, and the front surface of the LED display device is flat. When the LED display module needs to be removed from the box, the lock cylinder or the locking member is driven to switch the locking member from the locking position to the unlocking position. At this moment, the interference member rotates from the avoidance position to the interference position. However, since the LED display module is not removed from the box at this moment, an interference arm abuts against the connecting beam of the box under the action of the elastic linkage member. When the LED display module is removed from the box, and when the locking member moves forward by a distance with the display module body, the side of the connecting beam does not block the interference member, and the interference arm rotates to the front side of the connecting beam under the elastic force of the elastic linkage member, so that the interference member is in the interference position. Therefore, the technical solution of the present application effectively solves the problem in the related technology that missing locking is easily caused when an LED display module is mounted on a box by locks.

### BRIEF DESCRIPTION OF THE DRAWINGS

The accompanying drawings constituting a part of the present application are used to provide a further understanding of the present disclosure, and the exemplary embodiments of the present disclosure and the description thereof are used to explain the present disclosure, but do not constitute improper limitations to the present disclosure. In the drawings:

FIG. 1 shows a schematic front view of a locking member in an embodiment of an LED display device according to the present disclosure in a locking position.

FIG. 2 shows a schematic partially enlarged view at A of the LED display device of FIG. 1.

FIG. 3 shows a schematic cross-sectional view of the LED display device of FIG. 1.

FIG. 4 shows a schematic partially enlarged view at B of the LED display device of FIG. 3.

FIG. 5 shows a schematic front view of an embodiment of an LED display module according to the present disclosure.

FIG. 6 shows a schematic perspective view of a locking member of the LED display module of FIG. 5 in an unlocking position.

FIG. 7 shows a schematic partially enlarged view at C of the LED display module of FIG. 6.

FIG. 8 shows a schematic perspective view of the LED display module of FIG. 5 in a state where a lock is not mounted.

FIG. 9 shows a schematic partially enlarged view at D of the LED display module of FIG. 8.

FIG. 10 shows a schematic perspective view of an embodiment of a lock according to the present disclosure fitting a tool.

FIG. 11 shows a schematic perspective view of the lock of FIG. 10 fitting the tool from another angle.

FIG. 12 shows a schematic exploded view of the lock of FIG. 10.

The Drawings Include the Following Reference Signs:
10: LED display module; 21: display module body;
31: lock; 32: lock seat: 321: surrounding plate; 322: mounting groove; 323: limiting column; 324: positioning ball; 33: lock cylinder; 331: lock plate; 332: cylinder rod; 333: front operating hole; 334: limiting hole; 335: first positioning hole; 336: second positioning hole; 34: locking member; 341: second drive block; 342: locking arm; 35: interference member; 351: rotating sleeve; 352: interference arm; 353: first drive block; 36: torsion spring; 37: baffle plate;
41: magnetic attraction structure: 411: first magnetic attraction member; 412: second magnetic attraction member: 50: box: 51: connecting beam; 61: tool.

### DETAILED DESCRIPTION OF THE EMBODIMENTS

The technical solutions in the embodiments of the present disclosure will be clearly and completely described below with reference to the drawings in the embodiments of the present disclosure. It is apparent that the described embodiments are only a part of the embodiments of the present disclosure, not all of the embodiments. The following description of at least one exemplary embodiment is only illustrative actually, and is not used as any limitation for the present disclosure and the application or use thereof. Based on the embodiments of the present disclosure, all other embodiments obtained by those of ordinary skill in the art without inventive effort shall fall within the scope of protection of the present disclosure.

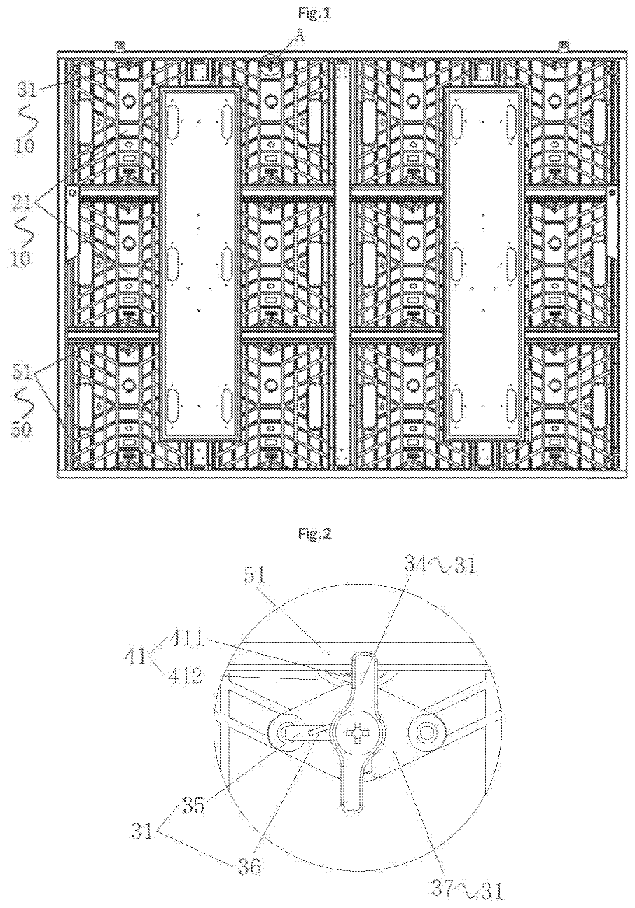

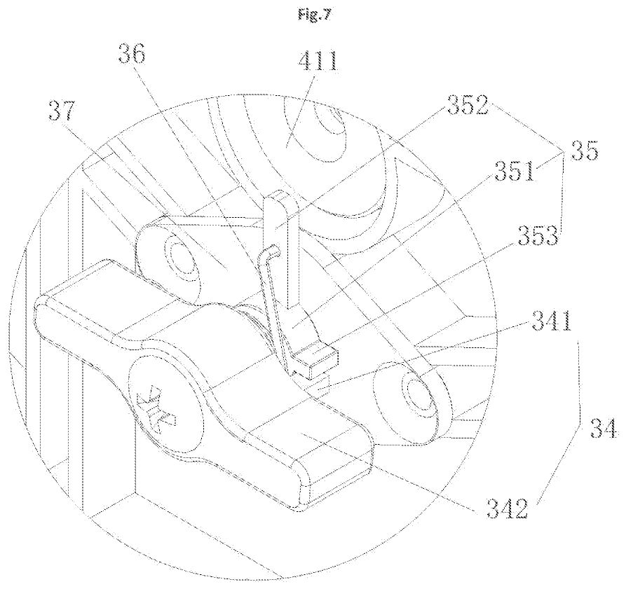

As shown in FIGS. 1 to 7, an LED display module of the present embodiment is mounted on a connecting beam 51 of a box 50. The LED display module 10 includes a display module body 21 and a lock 31. The lock 31 includes: a lock seat 32, a lock cylinder 33, a locking member 34, an interference member 35, and an elastic linkage member. The lock seat 32 is arranged on a rear side of the display module body 21. The lock cylinder 33 is rotatably arranged in the lock seat 32. The locking member 34 is connected with the lock cylinder 33 and rotates synchronously therewith. The locking member 34 has a locking position abutting against a rear side of the connecting beam 51 to lock the display module body 21 on the connecting beam 51, and an unlocking position avoiding the connecting beam 51 whereby the display module body 21 is separable from the box 50. The interference member 35 is rotatably sleeved on the lock cylinder 33, and the interference member 35 is spaced apart from the locking member 34 along the axial direction of the lock cylinder 33. The interference member 35 has an interference position where the interference member locates on a front side of the connecting beam 51 to lift forward the display module body 21 and an avoidance position where the interference member avoids the connecting beam 51. The elastic linkage member is arranged between the locking member 34 and the interference member 35. When the locking member 34 is in the unlocking position, the interference member 35 is driven to the interference position by the elastic linkage member. When the locking member 34 rotates from the unlocking position to the locking position, the interference member 35 rotates from the interference position to the avoidance position.

With the technical solution of the present embodiment, the locking cylinder 34 is connected with the lock cylinder 33 and rotates synchronously with the lock cylinder 33. The locking member 34 has a locking position abutting against a rear side of the connecting beam 51 to lock the display module body 21 on the connecting beam 51, and an unlocking position avoiding the connecting beam 51 so that the display module body 21 is separable from the box 50. When operating from a front side of the LED display module 10, the rotation of the lock cylinder 33 is driven by using a tool 61 to lock the display module body 21 on the connecting beam 51 or to separate the display module body 21 from the box 50. When operating from a rear side of the LED display module 10, the rotation of the locking member 34 is directly driven to lock the display module body 21 on the connecting beam 51 or to separate the display module body 21 from the box 50. The interference member 35 is rotatably sleeved on the lock cylinder 33. And the interference member 35 is spaced apart from the locking member 34 along the axial direction of the lock cylinder 33, the interference member 35 has an interference position located on a front side of the connecting beam 51 to lift forward the display module body 21 and an avoidance position staggered from the connecting beam 51. The elastic linkage member is arranged between the locking member 34 and the interference member 35 to enable the locking member 34 to drive the interference member 35 to switch between the interference position and the avoidance position by means of elasticity or linkage. When the locking member 34 is in the unlocking position, the interference member 35 is driven to the interference position by the elastic linkage member, and when the locking member 34 rotates from the unlocking position to the locking position, the interference member 35 rotates from the interference position to the avoidance position. In the process of mounting the LED display module 10 of the LED display device on the box 50, when the locking member 34 is in the unlocking position, under the action of the elastic linkage member acting as an elastic force, the interference member 35 is located on the front side of the connecting beam 51 so as to lift forward the display module body 21, so that a front surface of the LED display device is uneven, thereby reminding an operator to drive the lock cylinder 33 so as to lock the display module body 21 on the connecting beam 51, and avoiding the occurrence of missing locking. At this moment, the rotation of the lock cylinder 33 is driven by using a tool 61 or the rotation of the locking member 34 is directly driven, so that the locking member 34 is in the locking position, under the action of the elastic linkage member acting as a linkage, the interference member 35 rotates together with the locking member 34, and the interference member 35 can be in the avoidance position. At this moment, there is no interference between the LED display module 10 and the box 50, and since the interference member 35 is in the avoidance position staggered from the connecting beam 51, the LED display device can be fixed to the box 50, and the front surface of the LED display device is flat. When the LED display module 10 needs to be removed from the box 50, the lock cylinder 33 or the locking member 34 is driven to switch the locking member 34 from the locking position to the unlocking position. At this moment, the interference member 35 rotates from the avoidance position to the interference position. However, since the LED display module 10 is not removed from the box 50 at this moment, an interference arm 352 abuts against the connecting beam 51 of the box 50 under the action of the elastic linkage member. When the LED display module 10 is removed from the box 50, and when the locking member 34 moves forward by a distance with the display module body 21, the side of the connecting beam 51 does not block the interference member 35, and the interference arm 352 rotates to the front side of the connecting beam 51 under the elastic force of the elastic linkage member, whereby the interference member 35 is in the interference position. Therefore, the technical solution of the present embodiment effectively solves the problem in the related technology that missing locking is easily caused when an LED display module is mounted on a box through a lock.

It should be noted that in addition to the interference position, the interference member 35 is in the avoidance position in other positions, and the process of the interference member 35 rotating from the interference position to the avoidance position can be realized by the above-mentioned linkage of the elastic linkage member to make the locking member 34 drive the interference member 35 to rotate together and can also be realized manually. Also, in the present embodiment, the locking member 34 is in the shape of a handle, thereby facilitating direct operation by an operator from the rear side of the LED display module 10 to lock the display module body 21 on the connecting beam 51 or to separate the display module body 21 from the box 50.

In the related technology, since the LED display module is mounted on the box by multiple magnetic attraction structures, there is a risk of the LED display module falling from the box due to the magnet demagnetization potential caused by impact, high temperature, magnetic field influence, aging for a long time, etc.

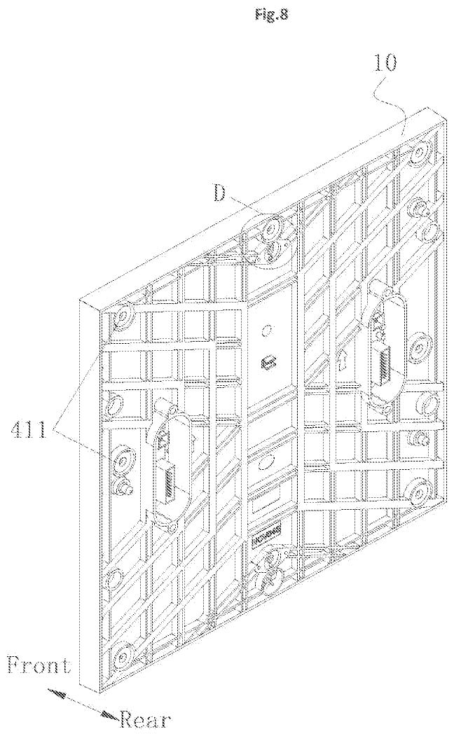

In order to solve the above-mentioned problem, as shown in FIGS. 1 to 9, the display module body 21 of the present embodiment is mounted on the connecting beam 51 by multiple magnetic attraction structures 41. When the locking member 34 is in the unlocking position, the LED display module 10 is magnetically attracted onto the box 50, and under the action of the elastic linkage member, the interference member 35 is in the interference position. At this moment, the interference member 35 is located on the front side of the connecting beam 51 to lift forward the display module body 10, so that a front surface of the LED display device is uneven, thereby reminding the operator to drive the lock cylinder 33 so as to lock the display module body 21 on the connecting beam 51, and avoiding the occurrence of missing locking. At this moment, the rotation of the lock cylinder 33 is driven by using a tool 61 or the rotation of the locking member 34 is directly driven, so that the locking member 34 is in the locking position, and under the action of the linkage of the elastic linkage member, the interference member 35 is in the avoidance position. At this moment, the LED display module 10 is magnetically attracted onto the box 50. The interference member 35 is located in the avoidance position where the interference member avoid the connecting beam 51, so that the LED display device can be magnetically attracted onto the box 50 and the front surface of the LED display device is flat. Since the locking member 34 can lock the display module body 21 on the connecting beam 51, the LED display module 10 will not fall down from the box 50 when the magnetic attraction fails, and the occurrence of missing locking can be avoided due to the arrangement of the interference member 35. Therefore, the technical solution of the present embodiment effectively solves the problem of the risk of an LED display module falling from a box when an LED display device in the related technology uses a magnetic attraction structure to mount the LED display module on the box.

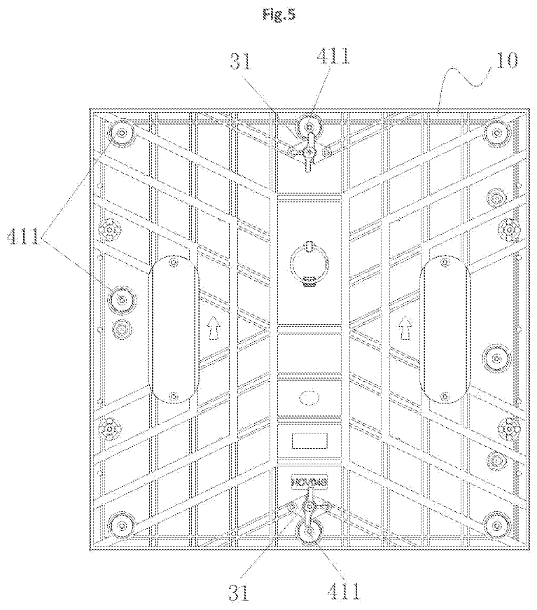

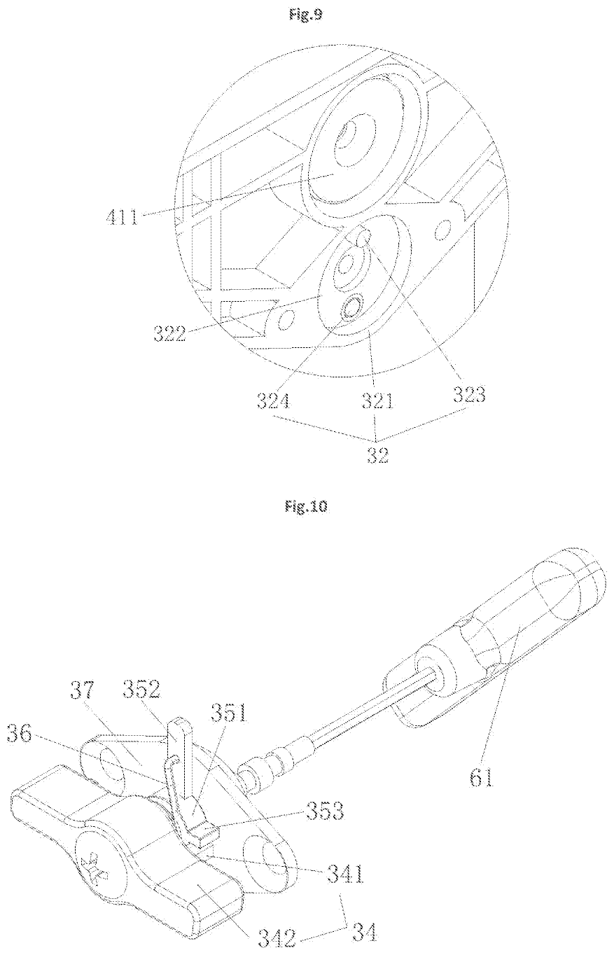

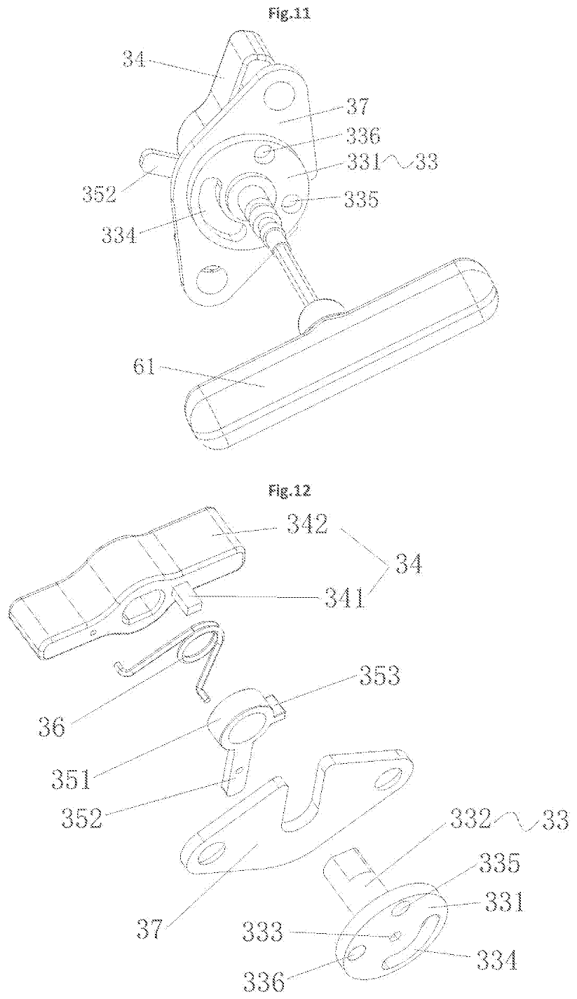

As shown in FIGS. 5 to 12, the interference member 35 includes a rotating sleeve 351 sleeved outside of the lock cylinder 33 and an interference arm 352 connected with an outer side wall of the rotating sleeve 351, a first end of the elastic linkage member is connected with the locking member 34, and a second end of the elastic linkage member is connected with the interference arm 352. The LED display module 10 of the LED display device is mounted on the box 50 by using the magnetic attraction structure 41. When the LED display module 10 needs to be removed from the box 50, the lock cylinder 33 or the locking member 34 is driven to switch the locking member 34 from the locking position to the unlocking position. At this moment, the interference member 35 rotates from the avoidance position to the interference position. However, since the LED display module 10 is not removed from the box 50 at this moment, an interference arm 352 abuts against the connecting beam 51 of the box 50 under the action of the elastic linkage member. When the LED display module 10 is removed from the box 50, and when the locking member moves forward by a distance with the LED display module 10, the side of the connecting beam does not block the interference member 35, and the interference arm 352 rotates to the front side of the connecting beam 51 under the elastic force of the elastic linkage member, so that the interference member 35 is in the interference position. When the LED display module 10 is magnetically attracted onto the box 50, the interference member 35 is in the interference position, and the LED display module 10 can be lifted forward, so as to realize self-inspection, play a safety role, and avoid the occurrence of missing locking.

As shown in FIGS. 5 to 12, the elastic linkage member includes a torsion spring 36, an end portion of a first torsion arm of the torsion spring 36 is inserted into the locking member 34, and an end portion of a second torsion arm of the torsion spring 36 is inserted into the interference arm 352. The action of the torsion spring 36 allows the locking member 34 to generate a torsional force relative to the interference member 35, thereby facilitating the linkage fit of the locking member 34 with the interference member 35 upon rotation of the locking member 34. Meanwhile, the space occupied by the torsion spring 36 on the rear side of the LED display module 10 is smaller, so that the LED display module 10 is more compact. In addition, the torsion spring 36 can maintain the position of the locking member 34 and the interference arm 352 relatively fixed without an external force. In order to magnetically attract the LED display module 10 onto the box 50, the locking member 34 firstly needs to rotate from the unlocking position to the locking position. In the process of rotating the locking member 34 from the unlocking position to the locking position, the locking member 34 drives the torsion spring 36 to rotate and enables the torsion spring 36 to link with the interference arm 352. The interference arm 352 rotates with the torsion spring 36. The interference arm 352 can rotate from the interference position to the avoidance position. There is no interference between the LED display module 10 and the box 50, so that the LED display module 10 is magnetically attracted onto the box 50.

In the present embodiment, the LED display module 10 of the LED display device is mounted on the box 50 by using the magnetic attraction structure 41. When the LED display module 10 needs to be removed from the box 50, the lock cylinder 33 or the locking member 34 is driven to switch the locking member 34 from the locking position to the unlocking position. At this moment, the interference member 35 rotates from the avoidance position to the interference position. However, since the LED display module 10 is not removed from the box 50 at this moment, the interference arm 352 abuts against the connecting beam 51 of the box 50 under the action of the torsion spring 36. When the LED display module 10 is removed from the box 50, the interference arm 352 rotates to the front side of the connecting beam 51 under the action of the torsion force of the torsion spring 36, and the interference member 35 is maintained at the interference position. When the LED display module 10 is magnetically attracted onto the box 50, the interference member 35 is in the interference position, and the LED display module 10 can be lifted forward, so as to avoid the occurrence of missing locking. The locking member 34 has a positioning ball 324 in positioning fit, so that the locking member 34 will not be separated from the unlocking position under the action of the torsion force of the torsion spring 36.

As shown in FIGS. 5 to 12, the interference member 35 further includes a first drive block 353 connected with the outer side wall of the rotating sleeve 351, the first drive block 353 is spaced apart from the interference arm 352, and the locking member 34 includes a locking arm 342 and a second drive block 341 arranged on the side of the locking arm 342 facing the rotating sleeve 351. The locking arm 342 has a locking position for locking the display module body 21 on the connecting beam 51 and an unlocking position for separating the display module body 21 from the box 50. The dimension of the interference arm 352 extending along the radial direction of the rotating sleeve 351 is greater than the dimension of the first drive block 353 extending along the radial direction of the rotating sleeve 351. In this way, the first drive block 353 is not located on the front side of the connecting beam 51 when the interference 35 rotates, thereby not affecting the mounting of the LED display module 10 on the box 50.

In the present embodiment, the second drive block 341 is in drive fit with the first drive block 353, so that the drive force applied by the second drive block 341 to the first drive block 353 is greater than the torsion force applied by the torsion spring 36 to the interference arm 352. Thus, the interference member 35 can be driven to rotate from the interference position to the avoidance position when the locking member 34 rotates from the unlocking position to the locking position. In this way, since the LED display module 10 is magnetically attracted to the box 50, there is a large magnetic attraction force therebetween. When the locking member 34 is switched from the unlocking position to the locking position, the second drive block 341 of the locking member 34 driving the first drive block 353 of the interference member 35 to rotate can not only overcome the above-mentioned magnetic attraction force, but also link with the torsion spring 36 to rotate together around the lock cylinder 33 so as to rotate the interference member 35. In this way, the interference member 35 can quickly rotate from the interference position to the avoidance position in drive fit of the first drive block 353 with the second drive block 341.

In the present embodiment, a center line of the first drive block 353 and a center line of the interference arm 352 form an angle of 90° on a front projection plane in the axial direction of the rotating sleeve 351 of the interference member 35. Definitely, in the embodiments not shown, the center line of the first drive block 353 and the center line of the interference arm 352 may also form an angle of 80°, 83°, 85°, 87°, 93°, or 95°.

Specifically, the box includes a frame and a connecting beam connected with the inside of the frame. The connecting beam includes multiple cross beams and multiple longitudinal beams arranged across the multiple cross beams, the multiple cross beams are spaced apart in sequence from a first side edge of the frame to a second side edge of the frame, and the multiple longitudinal beams are spaced apart in sequence from a third side edge of the frame to a fourth side edge of the frame. The first side edge is parallel to the second side edge, the third side edge is perpendicular to the first side edge, and the third side edge is parallel to the fourth side edge. The two adjacent partial cross beams and the two adjacent partial longitudinal beams enclose a “square”-shaped hollowed-out through hole therebetween. The locking arm 342 is connected with the lock cylinder 33 through a screw and rotates synchronously with the lock cylinder 33, and has a locking position for locking the display module body 21 on the cross beam and an unlocking position for separating the display module body 21 from the cross beam.

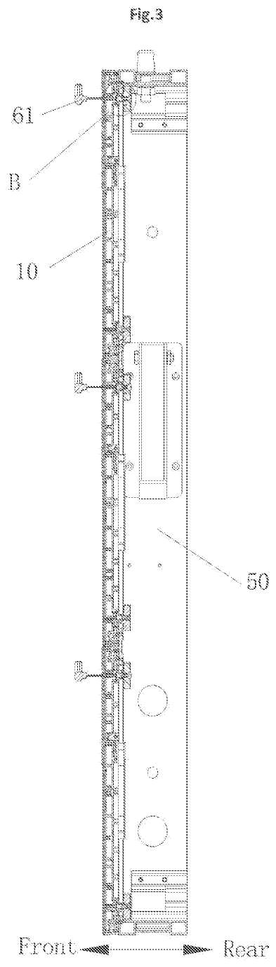

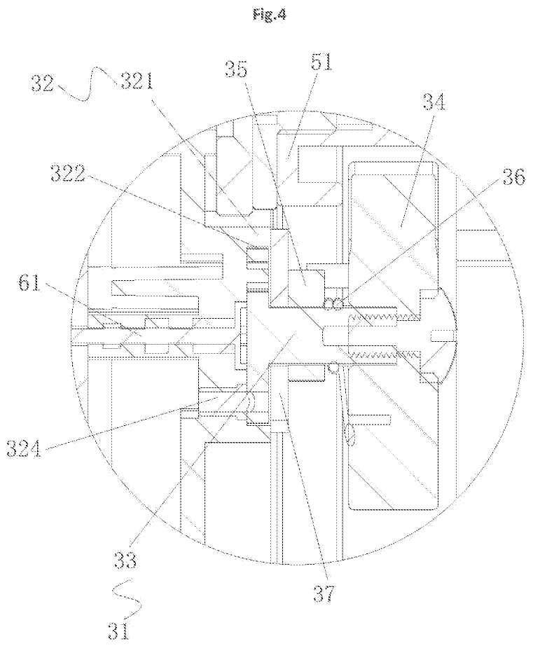

As shown in FIGS. 3, 4, and 10 to 12, the lock cylinder 33 includes a lock plate 331 rotatably arranged at the lock seat 32 and a cylinder rod 332 penetrating through the lock plate 331, and a front portion of the cylinder rod 332 is provided with a front operating hole 333. When operating from a front side of the LED display module 10, the tool 61 is used to protrude into the front operating hole 333 to drive the lock cylinder 33, so that the locking member 34 rotates to lock the display module body 21 on the connecting beam 51 or to separate the display module body 21 from the box 50. A rear portion of the cylinder rod 332 is in rotation stopping fit with the locking member 34, so that the lock cylinder 33 can simultaneously and angularly rotate with the locking member 34.

In the present embodiment, the display module body 21 is provided with an avoidance hole corresponding to the front operating hole 333, and the tool 61 is inserted into the front operating hole 333 through the avoidance hole to drive the rotation of the lock cylinder 33. The display module body includes a rear shell and a lamp panel module arranged on the front side of the rear shell, the lock seat of the lock is arranged on the rear side of the rear shell, the avoidance hole includes a first hole section arranged on the lamp panel module and a second hole section arranged on the rear shell, the first hole section and the second hole section are arranged in communication, and the tool 61 is used to protrude into the front operating hole 333 through the first hole section and the second hole section so as to drive the lock cylinder 33 to rotate.

In the present embodiment, the tool 61 is inserted into the front operating hole 333 through the lamp panel module on the display module body 21, the tool 61 is driven to rotate so as to rotate the lock cylinder 33, and the lock cylinder 33 rotates the locking member 34 so that the locking arm 342 of the locking member 34 abuts against the connecting beam 51 of the box 50, so that the locking arm 342 of the locking member 34 hooks against the connecting beam 51 to mount the display module body 21 on the box 50, and the display module body 21 does not fall off from the box 50 after the magnet fails, thereby serving as a safety function. Since the above-mentioned lock 31 is inserted into the front operating hole 333 by means of the tool 61 to drive the lock cylinder 33 so that the locking member 34 rotates by a certain angle to lock the display module body 21 on the connecting beam 51 or separate the display module body 21 from the box 50, the locking and unlocking operations can be performed without applying a great torsion force. In this way, the requirement for the diameter of the tool 61 is reduced accordingly, and the locking and unlocking operations can be performed by using the small-diameter tool 61, so that the diameter of the avoidance hole in the display module body 21 can be reduced accordingly. This can be applied to an outdoor LED display module body having a small space, so that even if the lamp space of the display module body is small, an avoidance hole can be provided between the above-mentioned lamp spaces without affecting the display effect and appearance of the LED display module.

In the present embodiment, the cylinder rod 332 is arranged coaxially with the lock plate 331.

As shown in FIGS. 5 to 12, the lock seat 32 is provided with a first limiting portion, the lock plate 331 is provided with a second limiting portion in limiting fit with the first limiting portion, and the first limiting portion is in limiting fit with the second limiting portion so as to limit the rotation range of the lock plate 331, so that the locking member 34 is switched between the unlocking position and the locking position. The rotation range of the lock plate 331 is limited to facilitate the locking and unlocking operations of an operator. In the present embodiment, the rotation range of the lock plate 331 is preferably 90°. Definitely, in the embodiments not shown in the figures, the rotation range of the lock plate 331 may also be 80°, 83°, 85°, 87°, 93°, or 95°.

As shown in FIGS. 5 to 12, the first limiting portion includes a limiting column 323, the second limiting portion includes a limiting hole 334, the limiting column 323 penetrates through the limiting hole 334, and the limiting hole 334 extends along the circumferential direction of the lock plate 331. The limiting column 323 has a first limiting position and a second limiting position in limiting fit with hole side walls at two ends of the limiting hole 334 respectively. When the limiting column 323 is in the first limiting position, the locking member 34 is in the unlocking position. When the limiting column 323 is in the second limiting position, the locking member 34 is in the locking position. When it is required to separate the display module body 21 from the box 50, the lock cylinder 33 is driven so that the locking member 34 is in the unlocking position. At this moment, since the limiting column 323 is in the first limiting position, the lock cylinder 33 cannot continue to rotate any more, so that an operator can know that the unlocking has been successful, so as to facilitate understanding of the locking operation. When it is required to lock the display module body 21 on the connecting beam 51, the lock cylinder 33 is driven so that the locking member 34 is in the locking position. At this moment, since the limiting column 323 is in the second limiting position, the lock cylinder 33 cannot rotate any more, so that the operator can know that it is locked in place, thereby further enabling the locking member 34 to be in the locking position, so that the display module body 21 is locked on the connecting beam 51 more reliably.

As shown in FIGS. 5 to 12, the lock 31 further includes a positioning ball 324 and a first positioning hole 335 and a second positioning hole 336 in positioning fit with the positioning ball 324, and the positioning ball 324 is arranged on the lock seat 32. The positioning ball 324 includes a positioning cylinder arranged on the lock seat 32, a bead arranged at an opening of the positioning cylinder facing the lock plate 331, and an elastic member arranged between the bead and the positioning cylinder, the bead can be in positioning fit with the first positioning hole 335 and the second positioning hole 336, the diameter of the positioning cylinder at the opening is smaller than the diameter of the bead, and more than half of the bead is located in the positioning cylinder. A portion of the bead of the positioning ball 324 protrudes into the first positioning hole 335 or the second positioning hole 336 under the action of an elastic member so that the positioning ball 324 is in positioning fit with the first positioning hole 335 or the second positioning hole 336. The first positioning hole 335 and the second positioning hole 336 are spaced apart on the lock plate 331, when the positioning ball 324 is in positioning fit with the first positioning hole 335, the locking member 34 is maintained in the unlocking position, and when the positioning ball 324 is in positioning fit with the second positioning hole 336, the locking member 34 is maintained in the locking position. When the locking member 34 is located between the locking position and the unlocking position, the bead of the positioning ball 324 abuts against the front surface of the lock plate 331. When the first positioning hole 335 of the lock plate 331 rotates to the positioning ball 324, the bead of the positioning ball 324 is popped up due to the elastic force of the elastic member, so that the operator can know that the unlocking is successful through sound and hand feeling. When the second positioning hole 336 of the lock plate 331 rotates to the positioning ball 324, the bead of the positioning ball 324 is popped up due to the elastic force of the elastic member, so that the operator can know that it is locked in place through sound and hand feeling.

Also, when the interference arm 352 abuts against the connecting beam 51 of the box 50, the elastic member of the positioning ball 324 applies an elastic force to stop the rotation of the lock plate 331 of the lock cylinder 33, which is greater than the torsion force applied to the locking member 34 by the torsion spring 36 to separate the locking member 34 from the locking position, so that the locking member 34 can be maintained in the locking position when the interference arm 352 abuts against the connecting beam 51 of the box 50.

In the present embodiment, when the positioning ball 324 is in positioning fit with the first positioning hole 335, the limiting column 323 is in the first limiting position, and the locking member 34 is in the unlocking position. When the positioning ball 324 is in positioning fit with the second positioning hole 336, the limiting column 323 is in the second limiting position, and the locking member 34 is in the locking position. The positioning ball 324 is preferably a flat stepped spring positioning ball.

As shown in FIGS. 5 to 12, the lock seat 32 includes a surrounding plate 321 and a mounting groove 322 provided in the surrounding plate 321. The lock 31 further includes a baffle plate 37 covering an opening of the mounting groove 322 and connected with the surrounding plate 321. The lock cylinder 33 includes a lock plate 331 rotatably arranged between the mounting groove 322 and the baffle plate 37. The mounting groove 322 is provided so that the lock plate 331 can be mounted in the lock seat 32, and the baffle plate 37 is arranged so that the lock plate 331 arranged between the mounting groove 322 and the baffle plate 37 does not escape from the mounting groove 322. In this way, in the present embodiment, the lock seat 32 is a part of the display module body 21. In the embodiments not shown in the drawings, the lock seat 32 and the display module body 21 are of a separate structure, and the lock seat 32 is independently mounted on the LED display module 10.

As shown in FIGS. 1 to 9, the display module body 21 is mounted on the connecting beam 51 through multiple magnetic attraction structures 41, each of the magnetic attraction structures 41 includes a first magnetic attraction member 411 and a second magnetic attraction member 412 in magnetic attraction fit, the first magnetic attraction member 411 is arranged on the display module body 21, and the second magnetic attraction member 412 is arranged on the connecting beam 51. There are multiple locks 31, at least one of the locks 31 is adjacent to one of the multiple magnetic attraction structures 41, and when the interference member 35 of the lock 31 is in the interference position, the interference member 35 is located between the first magnetic attraction member 411 and the second magnetic attraction member 412 of the magnetic attraction structure 41 adjacent the interference member 35. In this way, when the display module body 21 is to be magnetically attracted to the connecting beam 51, the first magnetic attraction member 411, which is not adjacent to the lock 31, can be in magnetic attraction fit with the corresponding second magnetic attraction member 412 to magnetically attract the display module body 21 onto the connecting beam 51. At this moment, the locking member 34 is in the unlocking position, the interference member 35 is in the interference position, and the interference member 35 is located between the first magnetic attraction member 411 and the second magnetic attraction member 412 of the magnetic attraction structure 41 adjacent the interference member 35. The front side of the corresponding LED display device is lifted forward, so that the surface of the front side of the LED display device has a protrusion, so as to prompt the operator that the lock 31 is unlocked, thereby playing a warning function to avoid the occurrence of missing locking. Further, the locking member 34 can be in the locking position, so that the display module body 21 is more reliably mounted on the connecting beam 51. Preferably, the first magnetic attraction member 411 and the second magnetic attraction member 412 are both magnets, or the first magnetic attraction member 411 is a magnet and the second magnetic attraction member 412 is a ferrous member.

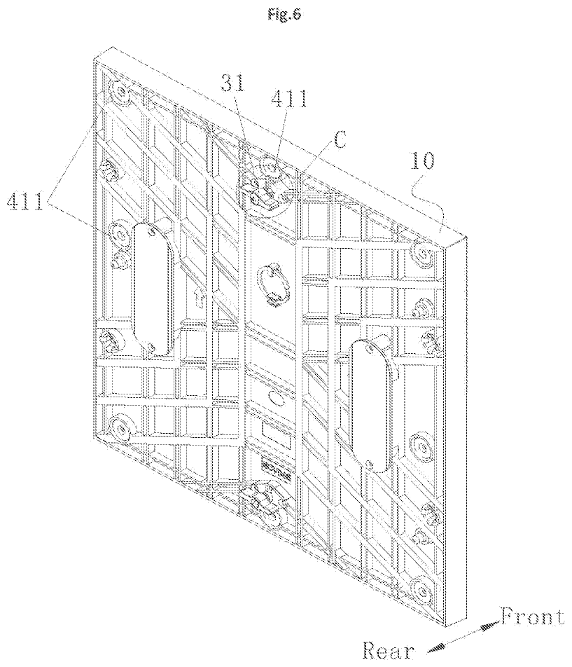

In the present embodiment, as shown in FIGS. 5 and 6, eight first magnetic attractions 411 are arranged on each display module body 21, three first magnetic attractions 411 are arranged on each of the opposite sides of the display module body 21, and one first magnetic attraction 411 is arranged on each of the other opposite sides. The connecting beam 51 corresponding to the display module body 21 is provided with second magnetic attraction members 412 corresponding to the first magnetic attraction members 411 on a one-to-one correspondence and in magnetic attraction fit. Two locks 31 are arranged on each display module body 21, and the two locks 31 are arranged on two sides of the display module body 21 provided with one first magnetic attraction member 411. In this way, when the display module body 21 is magnetically attracted onto the connecting beam 51, the locking member 34 is in the unlocking position, and the interference member 35 is in the interference position, and the interference member 35 is located between the first magnetic attraction member 411 and the second magnetic attraction member 412 of the magnetic attraction structure 41 adjacent the interference member 35. Therefore, the two side positions of the display module body 21 provided with one first magnetic attraction member 411 are lifted forward due to the interference of the interference member 35, so that the surface of the front side of the LED display device has a protrusion, so as to prompt the operator that the lock 31 is unlocked, thereby playing a warning function to avoid the occurrence of missing locking. Further, the locking member 34 can be in the locking position, so that the display module body 21 is more reliably mounted on the connecting beam 51.

As shown in FIGS. 1 to 4, according to another aspect of the present disclosure, an LED display device is provided. The LED display device includes a box 50 and an LED display module 10. A display module body 21 is mounted on a connecting beam 51 of the box 50, and the LED display module is the above-mentioned LED display module. Since the above-mentioned LED display module can solve the problem in the related technology that missing locking is easily caused when an LED display module is mounted on a box through a lock, the LED display device having the LED display module can also solve the same technical problem.

In the descriptions of the present disclosure, it will be appreciated that locative or positional relations indicated by “front, back, up, down, left, and right”, “horizontal, vertical, perpendicular, and horizontal”, “top and bottom” and other terms are locative or positional relations shown on the basis of the drawings, which are only intended to make it convenient to describe the present disclosure and to simplify the descriptions without indicating or impliedly indicating that the referring device or element must have a specific location and must be constructed and operated with the specific location, and accordingly it cannot be understood as limitations to the present disclosure. The nouns of locality “inner and outer” refer to the inner and outer contours of each component.

In addition, it is to be noted that terms “first”, “second” and the like are used to limit parts, and are only intended to distinguish corresponding parts. If there are no otherwise statements, the above terms do not have special meanings, such that they cannot be understood as limits to the scope of protection of the present disclosure.

The above is only the preferred embodiments of the present disclosure, not intended to limit the present disclosure. As will occur to those skilled in the art, the present disclosure is susceptible to various modifications and changes. Any modifications, equivalent replacements, improvements and the like made within the spirit and principle of the present disclosure should fall within the scope of protection of the present disclosure.

What is claimed is:

1. A Light Emitting Diode (LED) display module mounted on a connecting beam of a box, the LED display module comprising a display module body and a lock, the lock comprising:
a lock seat arranged on a rear side of the display module body;
a lock cylinder rotatably arranged in the lock seat;
a locking member connected with the lock cylinder and rotating synchronously with the lock cylinder, the locking member having a locking position abutting against a rear side of the connecting beam to lock the display module body on the connecting beam, and an unlocking position avoiding the connecting beam, so that the display module body is separable from the box;
an interference member rotatably sleeved on the lock cylinder, the interference member being spaced apart from the locking member along an axial direction of the lock cylinder, the interference member having an interference position where the interference member locates on a front side of the connecting beam to lift forward the display module body and an avoidance position where the interference member avoids the connecting beam; and
an elastic linkage member arranged between the locking member and the interference member,
wherein when the locking member is in the unlocking position, the interference member is driven to the interference position by the elastic linkage member, and when the locking member rotates from the unlocking position to the locking position, the interference member rotates from the interference position to the avoidance position.

2. The LED display module according to claim 1, wherein the interference member comprises a rotating sleeve sleeved outside of the lock cylinder and an interference arm connected with an outer side wall of the rotating sleeve, a first end of the elastic linkage member is connected with the locking member, and a second end of the elastic linkage member is connected with the interference arm.

3. The LED display module according to claim 2, wherein the elastic linkage member comprises a torsion spring, an end portion of a first torsion arm of the torsion spring is inserted into the locking member, and an end portion of a second torsion arm of the torsion spring is inserted into the interference arm.

4. The LED display module according to claim 2, wherein the interference member further comprises a first drive block connected with the outer side wall of the rotating sleeve, the first drive block is spaced apart from the interference arm, the locking member comprises a locking arm and a second drive block arranged on a side of the locking arm facing the rotating sleeve, a dimension of the interference arm extending along a radial direction of the rotating sleeve is greater than a dimension of the first drive block extending along a radial direction of the rotating sleeve, and the second drive block is in drive fit with the first drive block so that the interference member is driven to rotate from the interference position to the avoidance position when the locking member rotates from the unlocking position to the locking position.

5. The LED display module according to claim 1, wherein the lock cylinder comprises a lock plate rotatably arranged at the lock seat and a cylinder rod penetrating through the lock plate, a front portion of the cylinder rod is provided with a front operating hole, and a rear portion of the cylinder rod is in rotation stopping fit with the locking member.

6. The LED display module according to claim 5, wherein the lock seat is provided with a first limiting portion, the lock plate is provided with a second limiting portion in limiting fit with the first limiting portion, and the first limiting portion is in limiting fit with the second limiting portion so as to limit a rotation range of the lock plate, so that the locking member is switched between the unlocking position and the locking position.

7. The LED display module according to claim 6, wherein the first limiting portion comprises a limiting column, the second limiting portion comprises a limiting hole, the limiting column penetrates through the limiting hole, the limiting hole extends along a circumferential direction of the lock plate, the limiting column has a first limiting position and a second limiting position in limiting fit with hole side walls at two ends of the limiting hole respectively, when the limiting column is in the first limiting position, the locking member is in the unlocking position, and when the limiting column is in the second limiting position, the locking member is in the locking position.

8. The LED display module according to claim 5, wherein the lock further comprises a positioning ball and a first positioning hole and a second positioning hole in positioning fit with the positioning ball, the positioning ball is arranged on the lock seat, the first positioning hole and the second positioning hole are spaced apart on the lock plate, when the positioning ball is in positioning fit with the first positioning hole, the locking member is maintained in the unlocking position, and when the positioning ball is in positioning fit with the second positioning hole, the locking member is maintained in the locking position.

9. The LED display module according to claim 1, wherein
the display module body is mounted on the connecting beam through a plurality of magnetic attraction structures, each of the plurality of the magnetic attraction structures comprises a first magnetic attraction member and a second magnetic attraction member in magnetic attraction fit, the first magnetic attraction member is arranged on the display module body, and the second magnetic attraction member is arranged on the connecting beam; and
there are a plurality of locks, at least one of the plurality of the locks is adjacent to one of the plurality of magnetic attraction structures, and when the interference member of the lock is in the interference position, the interference member is located between the first magnetic attraction member and the second magnetic attraction member of the magnetic attraction structure adjacent the interference member.

10. An LED display device comprising a box and an LED display module, the display module body being mounted on a connecting beam of the box, wherein the LED display module is the LED display module according to claim 1.

11. The LED display device according to claim 10, wherein the interference member comprises a rotating sleeve sleeved outside of the lock cylinder and an interference arm connected with an outer side wall of the rotating sleeve, a first end of the elastic linkage member is connected with the locking member, and a second end of the elastic linkage member is connected with the interference arm.

12. The LED display device according to claim 11, wherein the elastic linkage member comprises a torsion spring, an end portion of a first torsion arm of the torsion spring is inserted into the locking member, and an end portion of a second torsion arm of the torsion spring is inserted into the interference arm.

13. The LED display device according to claim 11, wherein the interference member further comprises a first drive block connected with the outer side wall of the rotating sleeve, the first drive block is spaced apart from the interference arm, the locking member comprises a locking arm and a second drive block arranged on a side of the locking arm facing the rotating sleeve, a dimension of the interference arm extending along a radial direction of the rotating sleeve is greater than a dimension of the first drive block extending along a radial direction of the rotating sleeve, and the second drive block is in drive fit with the first drive block so that the interference member is driven to rotate from the interference position to the avoidance position when the locking member rotates from the unlocking position to the locking position.

14. The LED display device according to claim 10, wherein the lock cylinder comprises a lock plate rotatably arranged at the lock seat and a cylinder rod penetrating through the lock plate, a front portion of the cylinder rod is provided with a front operating hole, and a rear portion of the cylinder rod is in rotation stopping fit with the locking member.

15. The LED display device according to claim 14, wherein the lock seat is provided with a first limiting portion, the lock plate is provided with a second limiting portion in limiting fit with the first limiting portion, and the first limiting portion is in limiting fit with the second limiting portion so as to limit a rotation range of the lock plate, so that the locking member is switched between the unlocking position and the locking position.

16. The LED display device according to claim 15, wherein the first limiting portion comprises a limiting column, the second limiting portion comprises a limiting hole, the limiting column penetrates through the limiting hole, the limiting hole extends along a circumferential direction of the lock plate, the limiting column has a first limiting position and a second limiting position in limiting fit with hole side walls at two ends of the limiting hole respectively, when the limiting column is in the first limiting position, the locking member is in the unlocking position, and when the limiting column is in the second limiting position, the locking member is in the locking position.

17. The LED display device according to claim 14, wherein the lock further comprises a positioning ball and a first positioning hole and a second positioning hole in positioning fit with the positioning ball, the positioning ball is arranged on the lock seat, the first positioning hole and the second positioning hole are spaced apart on the lock plate, when the positioning ball is in positioning fit with the first positioning hole, the locking member is maintained in the unlocking position, and when the positioning ball is in positioning fit with the second positioning hole, the locking member is maintained in the locking position.

18. The LED display device according to claim 10, wherein
the display module body is mounted on the connecting beam through a plurality of magnetic attraction structures, each of the plurality of the magnetic attraction structures comprises a first magnetic attraction member and a second magnetic attraction member in magnetic attraction fit, the first magnetic attraction member is arranged on the display module body, and the second magnetic attraction member is arranged on the connecting beam; and
there are a plurality of locks, at least one of the plurality of the locks is adjacent to one of the plurality of magnetic attraction structures, and when the interference member of the lock is in the interference position, the interference member is located between the first magnetic attraction member and the second magnetic attraction member of the magnetic attraction structure adjacent the interference member.
